(19) United States
(12) Patent Application Publication
(10) Pub. No.: US 2015/0343572 A1
(43) Pub. Date: Dec. 3, 2015

(54) Window Clamp

(71) Applicant: Texas Instruments Incorporated, Dallas, TX (US)

(72) Inventors: Ruby Ann Maya Merto, Baguio City (PH); Wilmar Estandian Subido, Garland, TX (US)

(21) Appl. No.: 14/294,671

(22) Filed: Jun. 3, 2014

(51) Int. Cl. B23K 37/04; H01L 23/00

(52) U.S. Cl. CPC B23K 37/04; H01L 24/78; H01L 24/85

(57) ABSTRACT

A wire bonding window clamp including a frame structure defining a central clamp opening that has a flat bottom surface adapted to engage a leadframe sheet and at least one elongate strand of material extending between opposed portions of the frame structure and adapted to engage the leadframe sheet.

### BACKGROUND

Semiconductor devices, to be useful, must be electrically connected to one another or to other electronic devices. Leadframes made from conductive metal such as copper, silver or gold are often used to electrically connect a semiconductor device to other electronic devices. One popular and flexible method of connecting semiconductor devices to leadframes is wire bonding. Bond wires usually consist of aluminum, copper or gold. Bond wire diameters typically range from about 15 μm to several hundred micrometers in high-power applications. There are two basic types of wire bonding—ball bonding and wedge bonding.

Ball bonding usually uses a combination of heat, pressure and ultrasonic energy. In ball bonding, a small molten ball is formed at the end of the bond wire by application of a high voltage charge through a tool known as a capillary that holds and dispenses wire. The molten ball is placed on the electrical contact surface of a chip. The contact surface is usually copper or aluminum. A combination of heat, pressure and ultrasonic energy is then applied which creates a weld between the ball and the contact surface. The ball bond is sometimes referred to as the first bond because it is usually the first bond made in wire bonding of an IC chip/die to a leadframe.

In a die leadframe interconnection, the type of wire bond that is generally used to connect the second end of the bond wire to the leadframe is called a wedge bond or sometimes second bond. It is formed by crushing the end of the bond wire between the leadframe or other metal surface and the tip of the capillary tool.

The quality of wire bonds formed on a leadframe is dependent on a number of factors including the stability of the leadframe on a support plate of the bonding machine.

### BRIEF DESCRIPTION OF THE DRAWINGS

FIG. 1 is an isometric view of a prior art wire bonding machine supporting a leadframe.

FIG. 2 is a cross-sectional detail view of a portion of the prior art wire bonding machine FIG. 1.

FIG. 3 is a top plan view of an example embodiment of a window clamp engaged with a leadframe.

FIG. 4 is a cross-sectional elevation view of the window clamp and leadframe of FIG. 3.

FIG. 5 is an isometric bottom view of the window clamp of FIGS. 3 and 4.

FIG. 6 is and isometric bottom view of another embodiment of a window clamp.

FIG. 7 is a cross-sectional side elevation view of a QFN stack supported on a leadframe and engaged by a wire member of window clamp.

FIG. 8 is a flow chart illustrating a method of holding a leadframe in stable relationship with a leadframe support plate having vacuum holes adapted to be registered with the leadframe.

### DETAILED DESCRIPTION

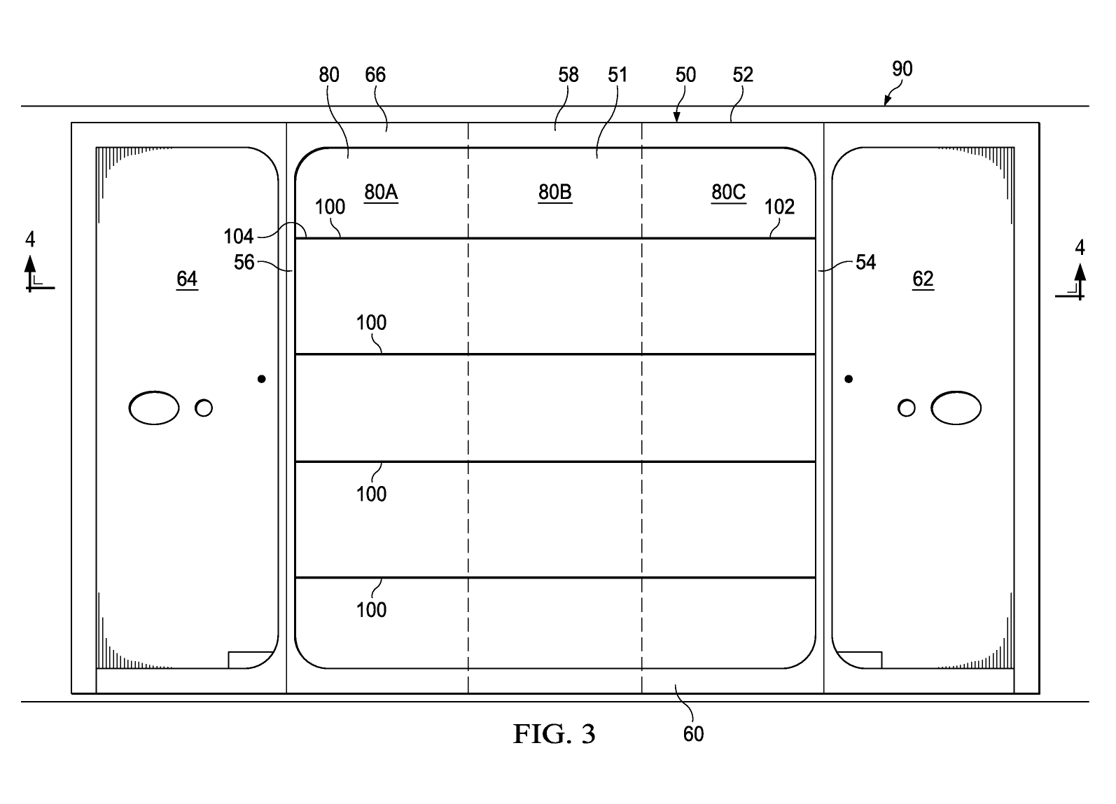

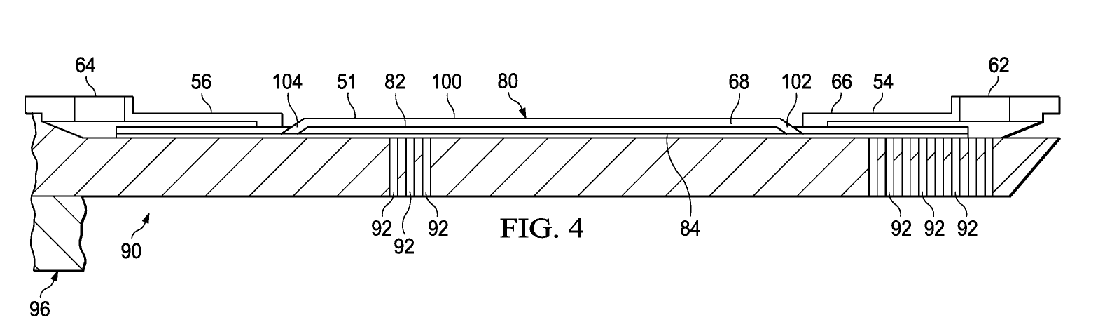

This specification, in general, discloses a wire bonding window clamp 50, FIGS. 3 and 4. The clamp 50 has a frame structure 52 defining a central clamp opening 51. The frame structure 52 has a flat bottom surface 68 that is adapted to engage an underlying leadframe sheet or strip 80. One or more elongate strands 100 of material extend between opposed portions of the frame structure 52. These strands 100 are also adapted to engage the leadframe strip 80.

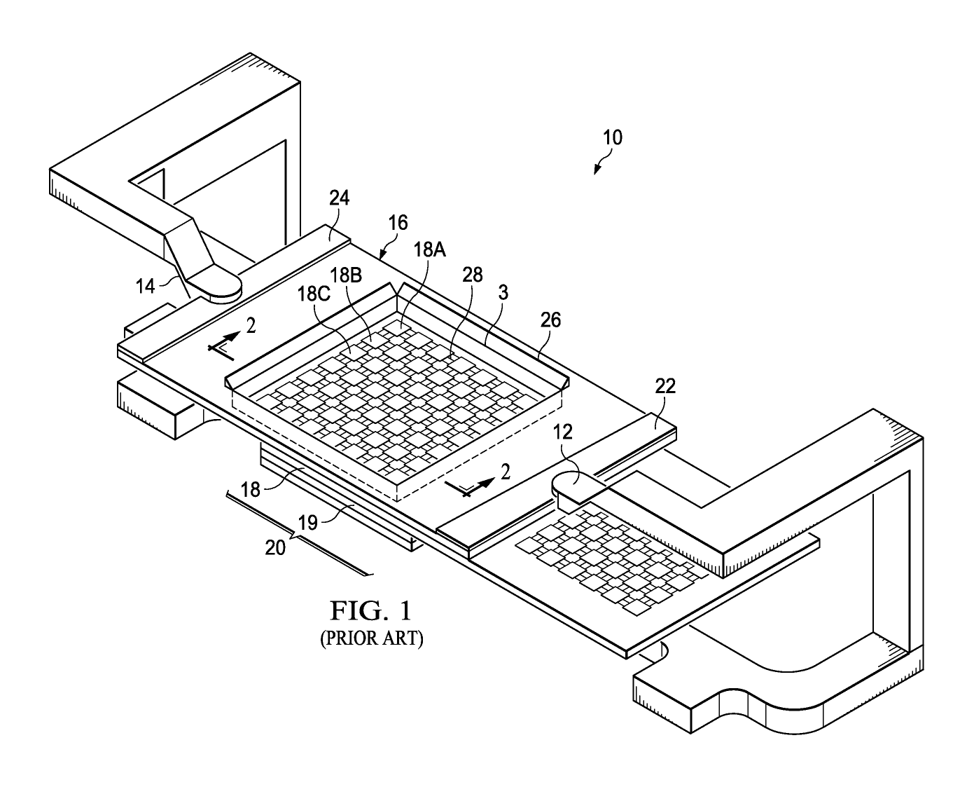

FIG. 1 illustrates a prior art wire bonding machine 10. The wire bonding machine 10 has clamp holding arms 12, 14. These arms 12, 14 are adapted to engage a window clamp 16, which, in turn, engages a leadframe strip 18. The leadframe strip 18 has a plurality of integrally connected leadframes 18A, 18B, 18C, etc.

Leadframe strip 18 is supported on a leadframe support plate 19. The support plate 19 is supportive on a heater block 20. In some wire bonding machine embodiments 10, the leadframe strip 18 is directly supported by the heater block 20, and there is no separate support plate 19.

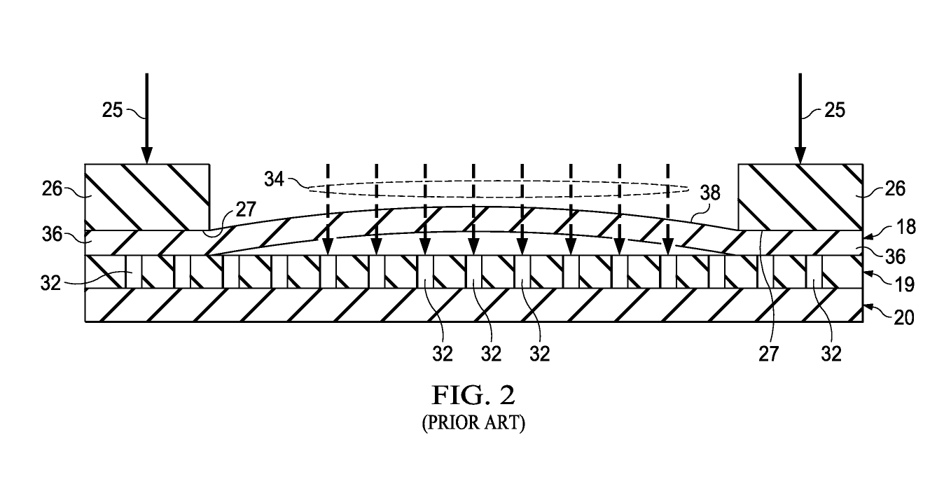

The window clamp 16 has a frame structure 26 that defines a clamp central opening 28. The bottom surface 27 of the frame structure 26 engages the underlying leadframe strip 18, as shown in FIG. 2. Window clamp 16 has a first and second support flange 22, 24 extending from opposite sides of the frame structure 26. Support flanges 22, 24 are engaged by the wire bonding machine holding arms 12, 14. The holding arms 12, 14 apply a downward force 25 on the support flanges that is transmitted to the frame structure 26 and the underlying portions 36 of leadframe strip 18. The purpose of this downward force 25 is to hold the strip 18 in stationary relationship with the leadframe support plate 19.

The support plate 19 has a number of tiny vacuum holes 32 on upper surface that are adapted to be registered with the leadframe strip 18. These vacuum holes are in fluid communication with a vacuum manifold (not shown) and apply a suction force to the bottom surface of the leadframe strip 18 to prevent it from vibrating during wire bonding operations. However, sometimes heat from the heater block 20 causes the frame strip 18 to expand. As a result, a portion 38 of the leadframe strip 18 that is not engaged by the window frame structure 26 buckles upwardly, as shown in FIG. 2. These buckled portions 38 of a leadframe strip 18 tend to vibrate during wire bonding operations performed on the strip 18. Such vibration tends to produce weak/defective wire bonds. Buckling of a leadframe strip 18 also uncovers some of the vacuum holes 32 beneath the buckled portion 38. This causes air 34 to enter the vacuum holes 32, reducing the vacuum force of the entire system. With the reduction in the system vacuum force, other portions of the leadframe strip 18 become disengaged from the plate 19, resulting in even more defective wire bonds.

Some window clamps are provided with a window pain type gridwork within the frame structure. However such gridworks, like the frame structures 26, are relatively rigid and may damage the underlying leadframe and/or associated devices, such as integrated circuit dies if the leadframe buckles. The risk of damage from such gridwork type clamps is particularly high with vertically stacked integrated circuit packages, such as QFN packages.

Window clamp embodiments, such as described with reference to FIGS. 3-7 below, may be used to overcome leadframe buckling and disengagement problems without causing damage to the underlying leadframe and/or associated devices.

FIG. 3 is a top plan view of a window clamp 50 and related structure and FIG. 4 is a side elevation view thereof. The window clamp 50 has a central opening 51 defined by a generally rectangular frame structure 52 that has a top surface 66 and a bottom surface 68. The frame structure 52 includes generally linear first, second, third and fourth frame structure portions 54, 56, 58 and 60. The first and second portions 54, 56 are generally parallel and extend perpendicular to the third and fourth portions 58, 60. A first support flange 62 extends laterally outwardly from the first linear portion 54 and a second support flange 64 extends laterally outwardly from the second linear portion 56.

Window clamp 50 is engaged with an underlying leadframe strip 80. Leadframe strip 80 is supported by a support plate 90, which has a plurality of vacuum holes 92 arranged along its entire length (only a few shown). The vacuum holes 92 are adapted to be placed in registration with the leadframe strip 80. In some embodiments the support plate 90 is supported by a heater block 96, as shown in FIG. 4. In other embodiments the leadframe strip is supported directly by a heater block. Such direct leadframe supporting heater blocks (not shown) generally have vacuum structure similar to the support plate 90.

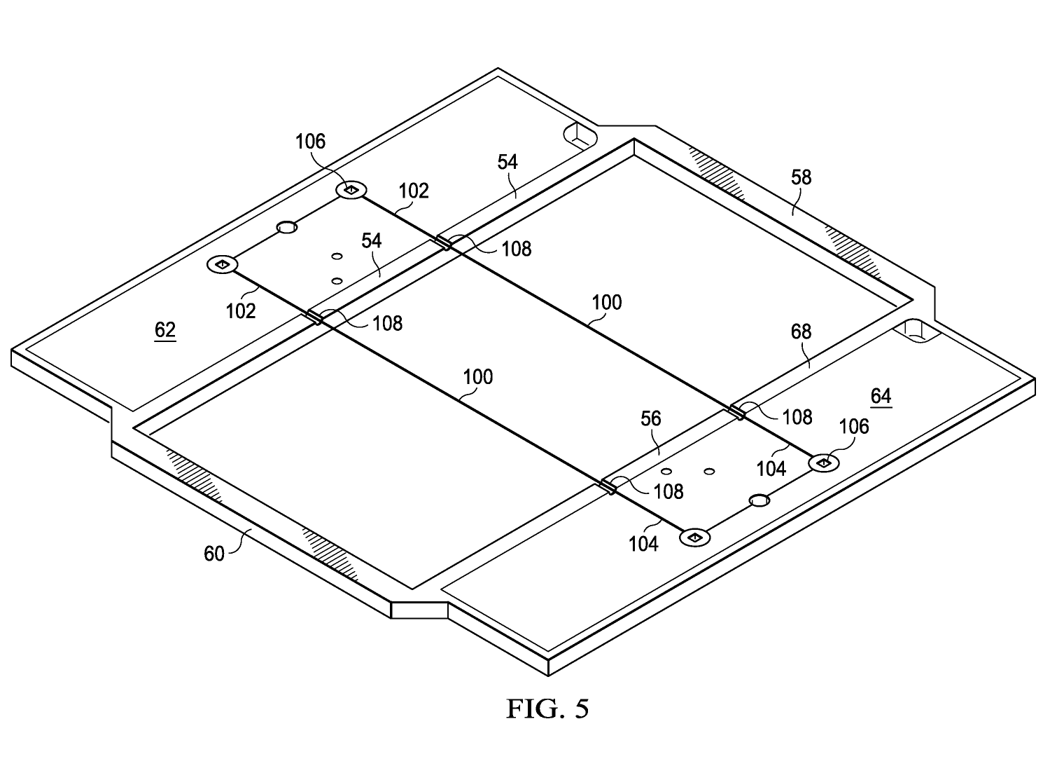

At least one wire 100 extends across the window clamp central opening 51. In the embodiment illustrated in FIGS. 3 and 4, four wires 100 are provided. Each wire has a first end 102 and a second and 104 that are attached to flange members 62, 64 as with screws 106 on the underside of the flange members or other attachment means. In the window clamp embodiment illustrated in FIG. 5 strands 100 are received in recesses 108 in the frame structure 52 such that bottom surfaces of the strands 100 are positioned in the same plane as the bottom surface 68 of the frame structure 52. The strands 100 may be pre-stressed, i.e., placed in tension before the screws 106 are tightened. In one embodiment, strands 100 are guitar wires or other music wires that have a relatively high elasticity modulus and high-strength. The high elasticity of such wires helps to prevent damage to the underlying leadframe strip 80 and associated structure and provides a cushioning effect as the window clamp engages the leadframe strip 80. In one example embodiment the strands 100 may be guitar wire or other music wire made from high tensile strength, high elastic limit stainless steel, and having a diameter of about 0.2 mm-0.3 mm and a length of about 70 mm. These example wires may have an elastic modulus of about 200 GPa. Wires of other sizes and elasticity may also be used depending upon the particular circumstances of such use.

As used in this specification the term “strand” means a length of flexible material capable of transmitting force when it is under tension, such as wire, wire rope, string, yarn, cable, other braided material, etc.

In the embodiment illustrated in FIG. 3, four parallel wires 100 have been stretched between opposite points on first and second frame portions 54, 56. As illustrated by FIG. 3, the portions of the leadframe sheet 80 that is centered within the window clamp central opening 51, may include 15 integrally connected leadframes 80A, 80B, 80C, etc. Wires 100 are positioned directly over the lateral connection lines of the leadframe rows. The wires 100 engage the top surface 82 of the leadframe strip 80, urging the bottom surface 84 of the strip against the top surface of the support plate 90.

This window clamp 50 of FIGS. 3 and 4 could also stably hold a single large leadframe (not shown) that could occupy the entire opening 51. In this situation the wires 100 would engage several different portions of the single leadframe.

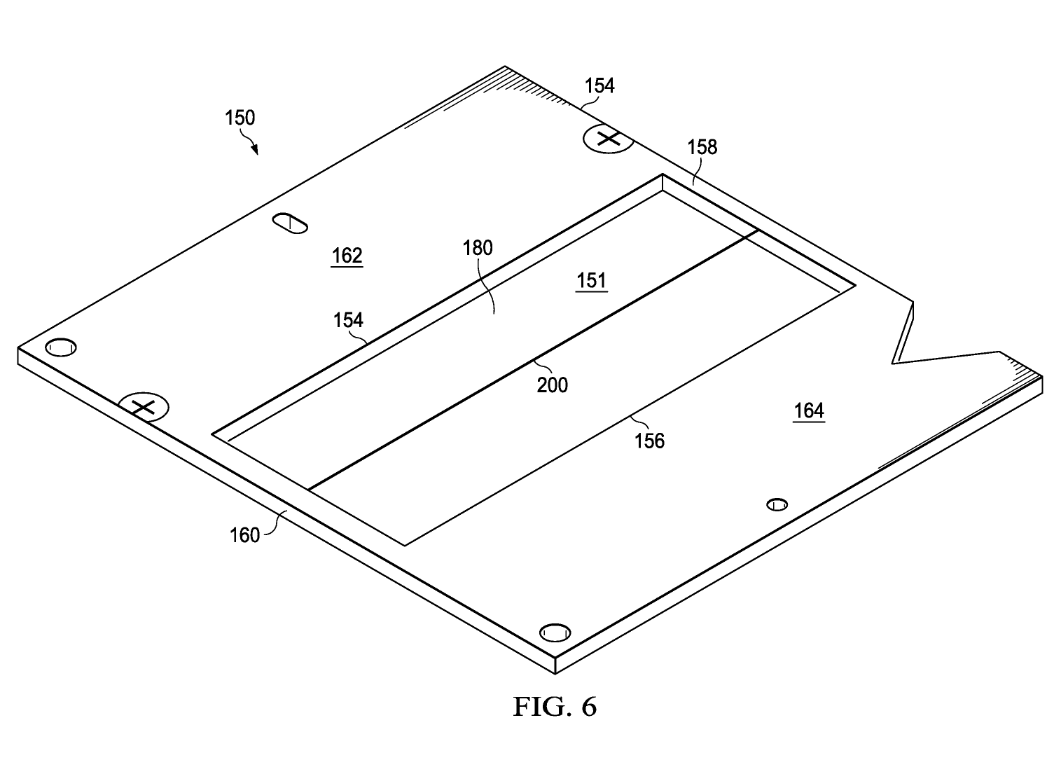

FIG. 5 illustrates an embodiment of a window clamp 50 in which only two wires 100 are used. In FIG. 5, the wires 100 may engage two interconnecting regions of three rows of leadframes on a leadframe sheet (not shown). FIG. 6 is a bottom isometric view of a window clamp 150 having a central opening 151 defined by four frame portions 154, 156, 158 and 160. In this embodiment a single wire 200 is a stretched between frame portions 158 and 160. In this embodiment the leadframe strip may have many interconnected leadframes or only a single leadframe. A single wire 100 is used to hold the leadframe/leadframe strip 180 against the underlying support plate (not shown).

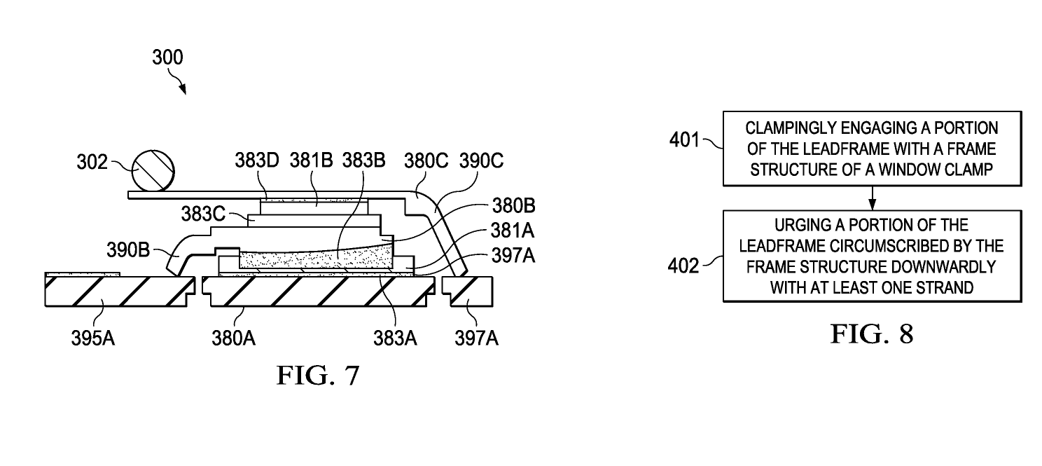

FIG. 7 illustrates a quad flat no lead package (“QFN”) type stack up assembly 300. Stack up assembly 300 includes a first leadframe 380A with a first die 381A mounted on it by a first adhesive layer 383A. The first die 381A has a second leadframe 380B mounted on it by a second adhesive layer 383B. A second die 381B is mounted on the second leadframe 380B by a third adhesive layer 383C. A third leadframe 380C is mounted on the second die 381B by a fourth adhesive layer 383D. A lead 390B of the second leadframe 380B is connected to one lead portion 395A of the first leadframe 380A. A lead 390C of the second leadframe 380B is connected to a second lead portion 397A of the first leadframe 380A. A wire 302 is attached to opposite portions of a window clamp (not shown), which have the same general construction as the window clamp 50 described above with reference to FIGS. 3 and 4. However, in this embodiment the wire 302 is stretched more because it is positioned on top of the stack up assembly 300 which has a much greater height than the thickness of a single leadframe, as in FIG. 4. For example, the height of stack up assembly 300 may be about 0.25 mm and the thickness of the leadframe strip 80 in FIGS. 4 and 5 may be about 0.2 mm. Even with such substantial stretching, the wire length and pre-stressing of the wire may be selected such that downward force exerted by the wire 302 on the stack up assembly 300 is relatively low so as to avoid damage to the various components.

FIG. 8 illustrates a method of holding a leadframe in stable relationship with a leadframe support plate having vacuum holes that are adapted to be registered with the leadframe. The method includes, as shown at block 401, clampingly engaging a portion of the leadframe with a frame structure of a window clamp. The method also includes, as shown at 402, urging a portion of the leadframe circumscribed by the frame structure downwardly with at least one strand.

Although certain embodiments of a window clamp have been described in detail herein, alternative embodiments of a window clamp will become obvious to those skilled in the art after reading this disclosure. It is intended that the appended claims be construed broadly to cover such alternative embodiments, except as limited by the prior art.

What is claimed is:

1. A wire bonding window clamp comprising:
a frame structure defining a central clamp opening and having a flat bottom surface adapted to engage a leadframe sheet; and
at least one elongate strand of material extending between opposed portions of said frame structure and adapted to engage the leadframe sheet.

2. The clamp of claim 1 wherein said at least one elongate strand of material comprises at least one wire.

3. The clamp of claim 2 wherein said frame structure comprises a first generally linearly extending frame structure portion and a second generally linearly extending frame structure portion and wherein said at least one wire has a first end engaged with said first frame structure portion and a second end engaged with said second frame structure portion.

4. The clamp of claim 3 wherein said first frame structure portion is positioned opposite said second frame structure portion.

5. The clamp of claim 3 wherein said at least one wire has a lower portion positioned in generally coplanar relationship with said frame structure flat bottom surface.

6. The clamp of claim 4 further comprising:
a first support flange extending laterally outwardly from said first frame structure portion; and
a second support flange extending laterally outwardly from said second frame structure portion; and
wherein said at least one wire stand engages at least one of said first and second support flanges.

7. The clamp of claim 6 wherein said at least one strand has a first end attached to said first support flange and a second end attached to said second support flange.

8. The clamp of claim 7 wherein said at least on strand is attached under tension to said first and second support flanges.

9. The clamp of claim 8 wherein said at least one strand has a first end attached to said first support flange by at least one screw and a second end attached to said second support flange by at least one screw.

10. The clamp of claim 4 further comprising:
a first support flange extending laterally outwardly from said first frame structure portion;
a second support flange extending laterally outwardly from said second frame structure portion;
a third frame structure portion extending generally perpendicular to said first and second frame structure portions; and
a fourth frame structure portion extending generally perpendicular to said first and second frame structure portions;
wherein said at least one strand extends between said third and fourth frame structure portions.

11. The clamp of claim 1 wherein said at least one elongate strand of material is constructed from a material having a higher modulus of elasticity than the material from which said frame structure portion is constructed.

12. The clamp of claim 1 wherein said at least one elongate strand of material is continuously under tension.

13. The clamp of claim 1 wherein said at least one elongate strand of material is music wire.

14. The clamp of claim 9 wherein said at least one strand comprises at least one elongate strand of guitar wire.

15. A wire bonding assembly comprising:
a window clamp comprising:
a generally rectangular frame structure having four orthogonally arranged frame structure portions, said frame structure portions having substantially coplanar bottom surfaces;
a plurality of strands, each having a lower portion substantially coplanar with said frame structure bottom surfaces and extending between opposed ones of said frame structure portions; and
a clip QFN comprising:
a first leadframe;
a vertical stack of components mounted on said first leadframe; and
a clip leadframe mounted on said vertical stack;
wherein said plurality of strands engage said clip leadframe.

16. A method of holding a leadframe in stable relationship with a leadframe support plate having vacuum holes adapted to be registered with the leadframe comprising:
clampingly engaging a portion of the leadframe with a frame structure of a window clamp; and
urging a portion of the leadframe circumscribed by the frame structure downwardly with at least one strand.

17. The method of claim 16 further comprising: attaching the strand to a bottom portion of the window clamp.

18. The method of claim 16 wherein urging a portion of the leadframe circumscribed by the frame structure downwardly with at least one strand comprises urging a portion of a bottom leadframe of a two dimensional package downwardly.

19. The method of claim 16 wherein urging a portion of the leadframe circumscribed by the frame structure downwardly with at least one strand comprises applying downward pressure on a clip leadframe sufficient to seal vacuum holes of a support plate on which the leadframe is mounted without damaging underlying structure of a QFN package.

20. The method of claim 16 wherein urging a portion of the leadframe circumscribed by the frame structure downwardly with at least one strand comprises urging the frame structure downwardly with a plurality of strands.
